(19) United States
(12) Patent Application Publication
(10) Pub. No.: US 2026/0060008 A1
(43) Pub. Date: Feb. 26, 2026

(54) MEMORY STRUCTURE AND METHOD

(71) Applicant: Taiwan Semiconductor Manufacturing Company, Ltd., Hsinchu (TW)

(72) Inventors: Chih-Yang Lin, Tainan City (TW); Tzy-Kuang Lee, Taichung (TW); Kuei-Yu Deng, Taichung City (TW); Chih-Hung Pan, Taichung (TW)

(73) Assignee: Taiwan Semiconductor Manufacturing Company, Ltd., Hsinchu (TW)

(21) Appl. No.: 18/813,512

(22) Filed: Aug. 23, 2024

(51) Int. Cl. H10N 70/00; H10B 63/00; H10N 70/20

(52) U.S. Cl. CPC H10N 70/021; H10B 63/30; H10N 70/063; H10N 70/24; H10N 70/841; H10N 70/8833

(57) ABSTRACT

A memory device structure, includes: a bottom electrode surrounded by a lower insulator layer; a dielectric layer disposed over the bottom electrode; a top electrode disposed over the dielectric layer; a vertical forming-voltage treatment area in an outer region of the device structure, the outer region including side regions of the bottom electrode, the dielectric layer, and the top electrode; and a forming effective region in an interior region of the device structure spaced away from a lateral edge the device structure and near a border between the dielectric layer and the top electrode, the forming effective region configured to cause the device structure to undergo a reversible change between a high resistance state associated with a first data state and a low resistance state associated with a second data state

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic cross sectional diagram depicting an example integrated circuit device that includes an RRAM cell, according to various embodiments.

FIG. 1B is a top view of an example portion of an RRAM array that includes a plurality of RRAM cells, according to various embodiments.

FIG. 2 is a schematic cross sectional diagram depicting an example semiconductor structure 200, according to some embodiments.

FIG. 3 is a flow diagram depicting an example method of fabricating an RRAM cell, according to various embodiments.

FIGS. 4A-4G, are schematic cross-sectional views of a semiconductor device at various stages of its fabrication process, according to various embodiments.

FIGS. 5A-5G are schematic cross-sectional views of another semiconductor device at various stages of its fabrication process, according to various embodiments.

FIGS. 6A-6G are schematic cross-sectional views of another semiconductor device at various stages of its fabrication process, according to various embodiments.

FIGS. 7A-7G are schematic cross-sectional views of another semiconductor device at various stages of its fabrication process, according to various embodiments.

FIGS. 8A-8C are schematic cross-sectional views of another semiconductor device at various stages of its fabrication process, according to various embodiments.

FIGS. 9A-9C are schematic cross-sectional views of another semiconductor device at various stages of its fabrication process, according to various embodiments.

FIGS. 10A-10C are schematic cross-sectional views of another semiconductor device at various stages of its fabrication process, according to various embodiments.

FIGS. 11A-11C are schematic cross-sectional views of another semiconductor device at various stages of its fabrication process, according to various embodiments.

FIG. 12A is a schematic cross-sectional view of an example semiconductor device, according to various embodiments.

FIGS. 12B and 12C are schematic cross-sectional views illustrating the relative size of the vertical forming-voltage treatment area in relation to the size of a RRAM cell, according to various embodiments.

FIG. 12D are cross-sectional views of an example semiconductor structure before vertical treatment and after vertical treatment, according to various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

As used herein, the terms such as “first,” “second” and “third” describe various elements, components, regions, layers and/or sections, these elements, components, regions, layers, and/or sections should not be limited by these terms. These terms may be only used to distinguish one element, component, region, layer, or section from another. The terms such as “first,” “second” and “third” when used herein do not imply a sequence or order unless clearly indicated by the context.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5° less than or equal to ±4°, less than or equal to ±3°, less than or equal to ±2°, less than or equal to ±1°, less than or equal to ±0.5°, less than or equal to ±0.1°, or less than or equal to ±0.05°.

Resistive random access memory (RRAM) cells include a dielectric data storage layer placed between two electrodes. Depending on voltages applied to the electrodes, the dielectric data storage layer will undergo a reversible change between a high resistance state associated with a first data state (e.g., a ‘0’ or ‘RESET’) and a low resistance state associated with a second data state (e.g., a ‘1’ or ‘SET’). Once a resistance state is set, an RRAM cell will retain the resistive state until another voltage is applied to induce a RESET operation (resulting in a high resistance state) or a SET operation (resulting in a low resistance state).

One performance metric to quantify the performance of an RRAM cell is endurance. The endurance of an RRAM cell is the number of set/reset cycles that can be applied to the RRAM cell before the cell degrades and begins to exhibit excess set/reset failures. The greater the endurance, the better the performance of the RRAM cell. It has been found that after a certain number of set/reset cycles, for example 10,000 set/reset cycles, the quality of some RRAM cells degrades, with increased cycling generally resulting in an increased number of set and/or reset failures. One phenomenon that has been noticed is the ‘RESET’ state trends to the ‘SET’ state with increased cycles. In other words, the dielectric data storage layer undesirably and sometimes irreversibly shifts to a low resistance state (e.g., ‘SET’ state) from a high resistance state (e.g., ‘RESET state).

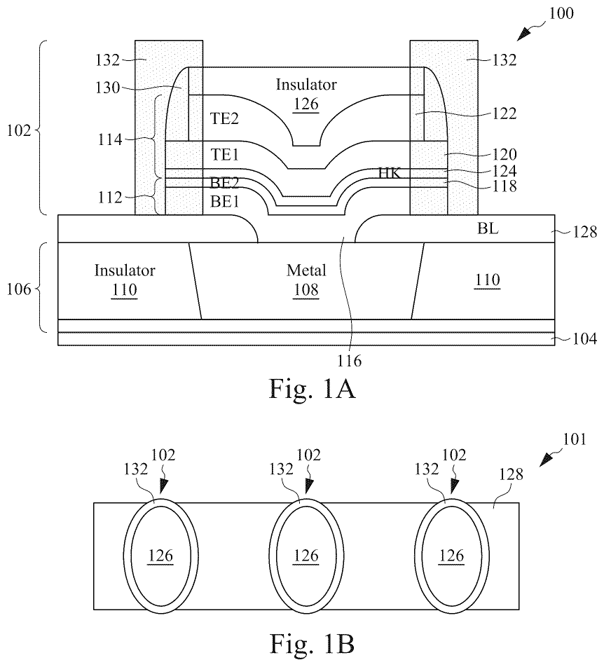

FIG. 1A is a schematic cross sectional diagram depicting an example integrated circuit device 100 that includes an RRAM cell 102 according to various embodiments. FIG. 1B is a top view of an example portion of an RRAM array 101 that includes a plurality of RRAM cells 102, according to various embodiments.

The integrated circuit device 100 is disposed over a substrate 104 and comprises an interconnect structure 106 formed over the substrate. The interconnect structure 106 comprises a lower metal interconnect layer 108 surrounded by a lower inter-level dielectric (ILD) layer 110. In some embodiments, the lower ILD layer 110 may comprise silicon dioxide (SiO₂), a low-x dielectric material, or an extreme low-x (ELK) dielectric material. The RRAM cell 102 is disposed over the lower metal interconnect layer 108 and comprises a bottom electrode 112 electrically coupled to the lower metal interconnect layer 108 and a top electrode 114 electrically coupled to an upper metal interconnect layer (not shown).

The bottom electrode 112 and the top electrode 114 may comprise titanium (Ti), tantalum (Ta), Hafnium (Hf), tantalum nitride (TaN), titanium nitride (TiN), ruthenium (Ru), Platinum (Pt), Gold (Au), Silver (Ag), Copper (Cu), Zirconium (Zr), Aluminum (Al), Lead (Pb), Tungsten (W), Iridium (Ir), Cobalt (Co), Zinc (Zn), Molybdenum (Mo), Gallium (Ga), Germanium (Ge), Palladium (Pd), Indium tin oxide (ITO), Indium zinc oxide (IZO) or other suitable material. The bottom electrode 112 and the top electrode 114 may be formed from a single film, composite film, or dopant film. In various embodiments, the bottom electrode 112 comprises a first layer 116 and a second layer 118. In various embodiments, the top electrode 114 comprises a first layer 120 and a second layer 122.

The bottom electrode 112 and the top electrode 114 are separated by an RRAM dielectric 124. The RRAM dielectric 124 comprises a material having a variable resistance configured to undergo a reversible phase change between a high resistance state and a low resistance. In various embodiments, the RRAM dielectric 124 may include a Hi K insulator such as one or more layers of Titanium oxide (TiO), tantalum oxide (TaO), Hafnium (HfO), titanium oxy nitride (TiON), tantalum oxy nitrid (TaON), ruthenium (RuO), silicon oxide (SiO), silver oxide (AgO), copper oxide (CuO), Zirconium oxide (ZrO), tungsten oxide (WO), Iridium oxide (IrO), cobalt oxide (CoO), zinc oxid (ZnO), Molybdenum oxide (MoO), Palladium oxide (PdO), Indium-oxygen (InO), Gallium oxide (GaO), lead oxide (PbO), aluminum oxide (AlO), stannous oxide (SnO), Germanium oxide (GeO), Boron monoxide (BO), BNO, and other suitable compounds. The RRAM dielectric 124 may be formed from a single film, composite film, or dopant film.

A hard mask (or insulator) 126 can be disposed on the top electrode 114. In various embodiments, the hard mask 126 may comprise SiO, silicon carbide (SiC), silicon nitride (SiN), silicon oxy carbide (SiOC), silicon oxy nitride (SiON), or other suitable films. The hard mask 126 may be formed from a single film, composite film, or dopant film.

In various embodiments, the RRAM cell 102 further comprises a lower dielectric layer 128 surrounding the first layer 116 of the bottom electrode 112. In various embodiments, the lower dielectric layer 128 may comprise SiO, silicon carbide (SiC), silicon nitride (SiN), silicon oxy carbide (SiOC), silicon oxy nitride (SiON), or other suitable films. The lower dielectric layer 128 may be formed from a single film, composite film, or dopant film. In various embodiments, the second layer 122 of the top electrode 114 and the hard mask 126 are recessed and a side wall 130 is formed in the recess. In various embodiments, the side wall 130 may comprise SiO, silicon carbide (SiC), silicon nitride (SiN), silicon oxy carbide (SiOC), silicon oxy nitride (SiON), or other suitable films.

The RRAM cell 102 further includes a vertical forming-voltage treatment area 132 in an outer region of the RRAM cell 102, wherein the outer region includes side regions of the bottom electrode 112, the RRAM dielectric 124, the top electrode 114, the hard mask 126, and the side wall 130. In various embodiments, the vertical forming-voltage treatment area 132 has been exposed to a heat treatment configured to cause a reduction in a lateral dimension of the forming effective region. In various embodiments, the vertical forming-voltage treatment area 132 includes a dopant comprising one or more of Oxygen (O), Nitrogen (N), Hydrogen (H), Fluorine (F), Carbon (C), Chlorine (Cl), and carbon tetrafluoride (CF₄). In various embodiments, the heat treatment was performed at a temperature range of approximately −250° C. to approximately 300° C., at a pressure of approximately 0 atm to approximately 8 atm, for a duration of up to approximately 3600 seconds. In various embodiments, a ratio of dopant to metal compounds in the vertical forming-voltage treatment area of the top electrode is greater than or equal to 5%. In various embodiments, the vertical forming-voltage treatment area extends into the RRAM structure a distance that is greater than 10% of a radius of the RRAM structure and less than 90% of the radius of the RRAM structure. In some embodiments, dopants may diffuse into the lower dielectric layer 128.

The vertical forming-voltage treatment area 132 can lead to better device performance. Formation of the vertical forming-voltage treatment area 132 can result in a concentration and size restriction in a forming region in the RRAM cell 102. A smaller forming voltage can result in due to a concentrated forming area.

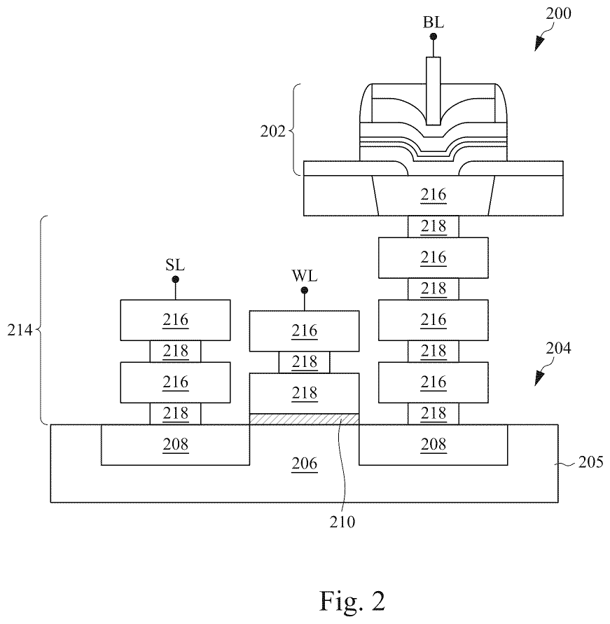

FIG. 2 is a schematic cross sectional diagram depicting an example semiconductor structure 200, according to some embodiments. Note that for clarity, not all features of the semiconductor structure 200 are illustrated in FIG. 2, and FIG. 2 may illustrate only a portion of the semiconductor structure formed. The semiconductor structure 200 includes an RRAM cell 202 (e.g., RRAM cell 102) that is electrically connected to a transistor device 204. The RRAM cell 202 and the transistor device 204 collectively form an RRAM device. As shown, a bit line (BL), select line (SL), and write line (WL) are electrically connected to the RRAM device for signal communication as desired.

The example transistor device 204 is a metal-oxide-semiconductor field effect transistor (MOSFET) device embedded in a dielectric layer (not shown) on a substrate 205. The example transistor device 204 includes a p-well 206, n+ regions 208 representing source/drain regions of the FET, an oxide layer 210 over a channel region of the FET, and a gate layer 212 over the oxide layer 210. In this example, the transistor device 204 is an n-FET device. In other examples, the transistor device 204 may be a p-FET device that includes an n-well and p+ regions representing source/drain regions of the FET. In certain embodiments, the transistor device 204 is formed by front-end-of-line (FEOL) processes and may be considered as an FEOL device.

The substrate 205 may be a semiconductor substrate, such as silicon, doped or undoped, or an active layer of a semiconductor-on-insulator (SOI) substrate. The semiconductor substrate may include other semiconductor materials, such as germanium; a compound semiconductor including silicon carbide, gallium arsenic, gallium phosphide, gallium nitride, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. Devices, such as transistors, diodes, capacitors, resistors, etc., may be formed in and/or on the substrate and may be interconnected by interconnect structures formed by, for example, metallization patterns in one or more dielectric layers over the substrate. FIG. 2 only illustrates a portion of the device that includes the RRAM cell 202 and the transistor device 204.

In some embodiments, the semiconductor structure 200 further includes, but is not limited thereto, other types of transistors, capacitors, resistors, or the like. The transistor device 204 is electrically connected to the RRAM cell 202 via an interconnection structure 214. In certain embodiments, the interconnection structure 214 is formed by middle-end-of-line (MEOL) processes and may be considered as an MEOL structure. In some embodiments, the interconnection structure 214 includes conductive lines 216 and conductive vias 218 embedded in an insulating layer (not shown) for interconnecting the transistor device 204 and the RRAM cell 202, and for electrically connecting the transistor device 204 with other above layers. Although only one transistor device 204 is shown in FIG. 2, it is well understood that multiple tiers or layers of transistors may be formed.

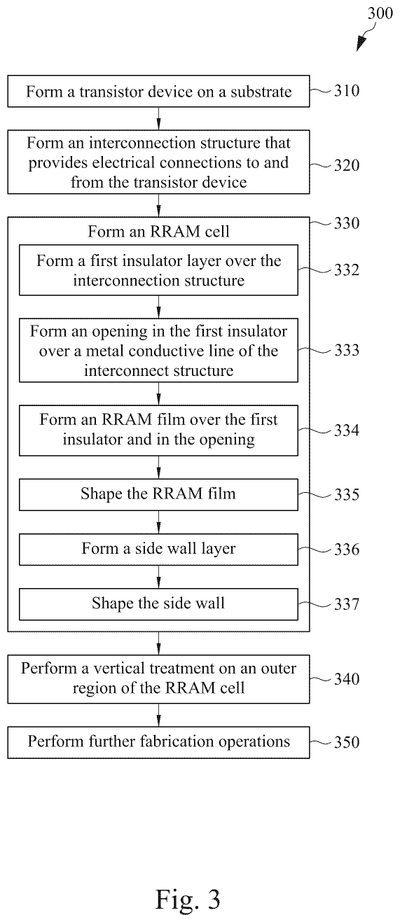

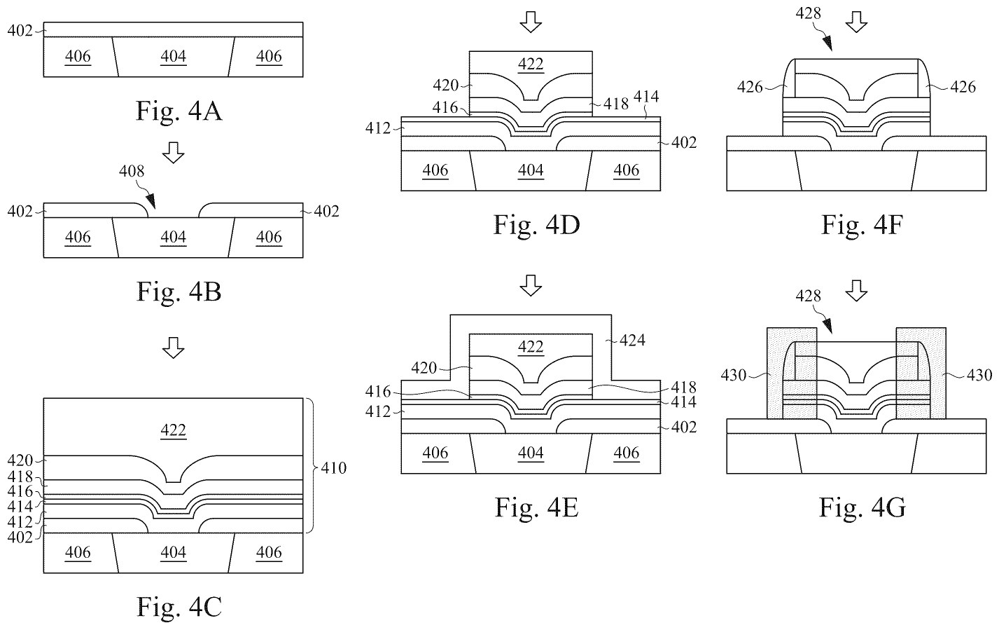

FIG. 3 is a flow diagram depicting an example method of fabricating an RRAM cell, according to some embodiments. For illustrative purposes, the operations illustrated in FIG. 3 will be described with reference to FIGS. 4A-4G, which show cross-sectional views of a semiconductor device at various stages of its fabrication process, according to some embodiments. Operations can be performed in a different order or not performed depending on specific applications. It should be noted that method 300 may not produce a complete semiconductor device. Accordingly, it is understood that additional processes can be provided before, during, and after method, and that some other processes may only be briefly described herein. In some figures, some reference numbers of components or features illustrated therein may be omitted to avoid obscuring other components or features; this is for ease of depicting the figures.

It is understood that parts of the semiconductor device may be fabricated by typical semiconductor technology process flow, and thus some processes are only briefly described herein. Further, the exemplary semiconductor devices may include various other devices and features, such as other types of devices such as additional transistors, bipolar junction transistors, resistors, capacitors, inductors, diodes, fuses, and/or other logic devices, etc., but is simplified for a better understanding of concepts of the present disclosure. In some embodiments, the exemplary devices include a plurality of semiconductor devices (e.g., transistors), including PFETs, NFETs, etc., which may be interconnected. Moreover, it is noted that the operations of method 300, including any descriptions given with reference to the Figures are merely exemplary and are not intended to be limiting beyond what is specifically recited in the claims that follow.

At block 310, the example method 300 includes forming a transistor device, such as a MOSFET embedded in a dielectric layer, on a substrate. The transistor device (e.g., transistor device 204) may be an n-channel or p-channel MOSFET formed in accordance with complementary MOS (CMOS) processes. In certain embodiments, the transistor device is formed by front-end-of-line (FEOL) processes and may be considered as a FEOL device. In some embodiments, the formation of the transistor device includes forming a p-well (e.g., p-well 206), n+ regions (e.g., n+ regions 208) representing source/drain regions of the transistor device, an oxide layer (e.g., oxide layer 210) over a channel region of the transistor device, and a gate layer (e.g., gate layer 212) over the oxide layer. In addition, conductive vias (e.g., conductive vias 218) are formed on the source and drain regions. In some embodiments, the gate layer includes a gate electrode and a gate dielectric layer.

At block 320, method 300 includes forming an interconnection structure (e.g., interconnection structure 214) that provides electrical connections to and from the transistor device. Forming the interconnection structure includes forming conductive lines and conductive vias (e.g., conductive lines 216 and conductive vias 218) that electrically connect to the transistor device. In some embodiments, the material of the conductive lines and the conductive vias may include a metal, such as copper, titanium, tungsten, aluminum, or a combination thereof. The conductive lines and the conductive vias may be formed by CVD or plating.

At operation 330, method 300 includes forming an RRAM cell. Forming the RRAM cell may include operations 332 to 337. At operation 332, the method 300 includes forming a first insulator layer over the interconnection structure. Referring to the example of FIG. 4A, in an embodiment of operation 332, a first insulator layer 402 is formed over a metal line 404 and interlayer dielectric (ILD) layer 406 of the interconnection structure. In various embodiments, the first insulator is formed by a suitable deposition technique. In various embodiments, the first insulator layer 402 may comprise an oxide, carbide, and/or nitride. In various embodiments, the first insulator layer 402 may comprise SiO, SiC, SiN, SiOC, SiON, or other suitable films. The lower dielectric layer 128 may be formed from a single film, composite film, or dopant film.

At operation 333, the method 300 includes forming an opening in the first insulator layer over a metal conductive line. Referring to the example of FIG. 4B, in an embodiment of operation 333, an opening 408 is formed in the first insulator layer 402 over a metal conductive line 404. In various embodiments, the opening is formed by patterning operations and a suitable etching technique.

At operation 334, the method 300 includes forming an RRAM film stack over the first insulator layer and in the opening. Referring to the example of FIG. 4C, in an embodiment of operation 334, an RRAM film stack 410 is formed over the first insulator layer 402 and in the opening 408. The RRAM film stack 410 includes a bottom electrode comprising a first bottom electrode layer 412 and a second bottom electrode layer 414, an RRAM dielectric layer 416 disposed over the bottom electrode, a top electrode comprising a first top electrode layer 418 and a second top electrode layer 420, and a second insulator layer 422. In various embodiments, the RRAM film stack 410 may be formed using suitable deposition techniques.

In various embodiments, the first bottom electrode layer 412, second bottom electrode layer 414, first top electrode layer 418, and second top electrode layer 420 may comprise titanium (Ti), tantalum (Ta), Hafnium (Hf), tantalum nitride (TaN), titanium nitride (TiN), ruthenium (Ru), Platinum (Pt), Gold (Au), Silver (Ag), Copper (Cu), Zirconium (Zr), Aluminum (Al), Lead (Pb), Tungsten (W), Iridium (Ir), Cobalt (Co), Zinc (Zn), Molybdenum (Mo), Gallium (Ga), Germanium (Ge), Palladium (Pd), Indium tin oxide (ITO), Indium zinc oxide (IZO) or other suitable material. These electrodes may be formed from a single film, composite film, or dopant film.

In various embodiments, the RRAM dielectric layer 416 may be formed from a material having a variable resistance configured to undergo a reversible phase change between a high resistance state and a low resistance. In various embodiments, the RRAM dielectric layer 416 may be formed from a Hi K insulator such as one or more layers of Titanium oxide (TiO), tantalum oxide (TaO), Hafnium (HfO), titanium oxy nitride (TiON), tantalum oxy nitrid (TaON), ruthenium (RuO), silicon oxide (SiO), silver oxide (AgO), copper oxide (CuO), Zirconium oxide (ZrO), tungsten oxide (WO), Iridium oxide (IrO), cobalt oxide (CoO), zinc oxid (ZnO), Molybdenum oxide (MoO), Palladium oxide (PdO), Indium-oxygen (InO), Gallium oxide (GaO), lead oxide (PbO), aluminum oxide (AlO), stannous oxide (SnO), Germanium oxide (GeO), Boron monoxide (BO), BNO, and other suitable compounds. In various embodiments, the RRAM dielectric layer 416 may be formed from a single film, composite film, or dopant film.

At operation 335, the method 300 includes shaping (e.g., etching) the RRAM film. In various embodiments, the RRAM film is shaped using suitable etching techniques. In various embodiments, the shaping includes etching the RRAM dielectric layer 416, first top electrode layer 418, second top electrode layer 420, and second insulator layer 422. Referring to the example of FIG. 4D, in an embodiment of operation 335, the RRAM film stack 410 has been etched into the shape of an RRAM cell. In particular, the RRAM dielectric layer 416, first top electrode layer 418, second top electrode layer 420, and second insulator layer 422 have been etched.

At operation 336, the method 300 includes forming a side wall layer. In various embodiments, forming the side wall layer involves depositing the side wall layer over the RRAM film layer using suitable deposition techniques. Referring to the example of FIG. 4E, in an embodiment of operation 336, a side wall layer 424 has been formed over the RRAM film stack 410. In various embodiments, the side wall layer 424 may comprise SiO, silicon carbide (SiC), silicon nitride (SiN), silicon oxy carbide (SiOC), silicon oxy nitride (SiON), or other suitable films.

At operation 337, the method 300 includes shaping the side wall layer (e.g., etching the side wall) to form the RRAM cell. In various embodiments, shaping the side wall layer involves removing (e.g., via etching operations) the sidewall layer from over the first bottom electrode layer 412, second bottom electrode layer 414, and RRAM dielectric layer 416, while leaving some of the side wall layer 424 over the first top electrode layer 418 and on sides of the second top electrode layer 420 and the second insulator layer 422. Referring to the example of FIG. 4F, in an embodiment of operation 337, the side wall 426 has been shaped to form the RRAM cell 428.

At operation 340, method 300 includes performing a vertical treatment on an outer region of the RRAM cell. In various embodiments, the outer region includes side regions of the first bottom electrode layer 412, second bottom electrode layer 414, RRAM dielectric layer 416, first top electrode layer 418, second top electrode layer 420, second insulator layer 422, and side wall 426. In various embodiments, performing a vertical treatment involves performing a heat treatment configured to cause a reduction in a lateral dimension of the forming effective region. In various embodiments, a hard mask may be used to protect central portions of the first bottom electrode layer 412, second bottom electrode layer 414, RRAM dielectric layer 416, first top electrode layer 418, second top electrode layer 420, second insulator layer 422, and side wall 426 from undergoing heat treatment. In various embodiments, performing a vertical treatment involves performing a heat treatment with a dopant comprising one or more of Oxygen (O), Nitrogen (N), Hydrogen (H), Fluorine (F), Carbon (C), Chlorine (Cl), and carbon tetrafluoride (CF₄). In various embodiments, performing a vertical treatment involves performing a heat treatment in a temperature range of approximately −250 C. to approximately 300° C., at a pressure of approximately 0 atm to approximately 8 atm, for a duration of up to approximately 3600 seconds. In various embodiments, the vertical treatment may result in a vertical forming-voltage treatment area in the outer region of the RRAM structure and a reduced size forming effective region in an interior region of the RRAM structure spaced away from a lateral edge the RRAM structure and near a border between the RRAM dielectric and the top electrode. The forming effective region is configured to cause the RRAM structure to undergo a reversible change between a high resistance state associated with a first data state and a low resistance state associated with a second data state. In various embodiments, a ratio of dopant to metal compounds in the vertical forming-voltage treatment area of the top electrode is greater than or equal to 5%. In various embodiments, the vertical forming-voltage treatment area extends into the RRAM structure a distance that is greater than 10% of a radius of the RRAM structure and less than 90% of the radius of the RRAM structure. Referring to the example of FIG. 4G, in an embodiment of operation 340, a vertical forming-voltage treatment area 430 is formed in the outer region of the RRAM cell 428.

At operation 350, method 300 includes performing further fabrication operations. Further fabrication operations may further include forming an interconnection over the RRAM cell 428. The interconnection may include more metallization structures including conductive vias and conductive lines. Further fabrication operations may also include further processing steps to complete an integrated circuit.

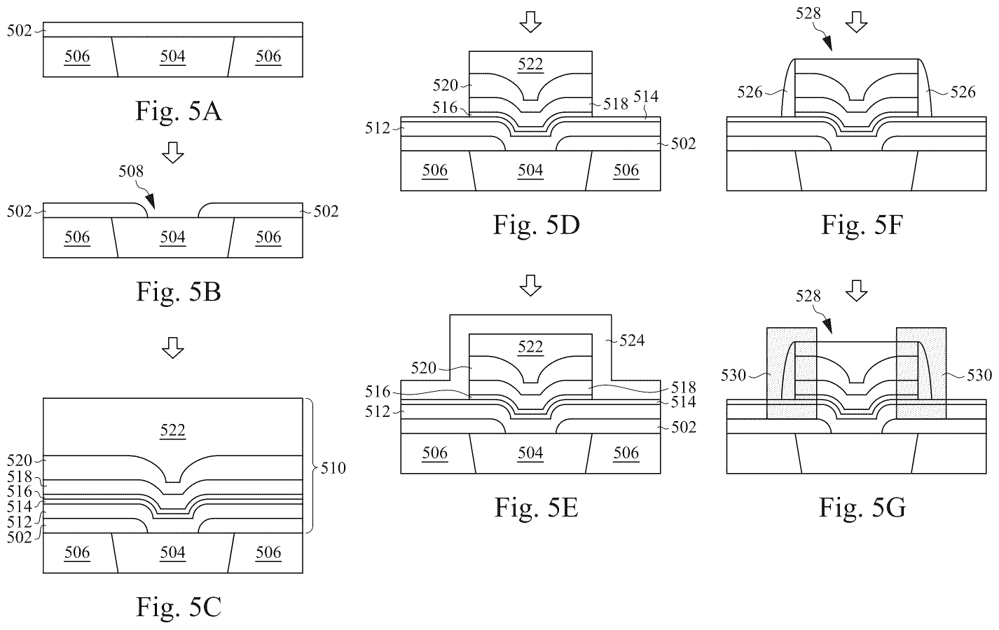

FIGS. 5A-5G are schematic cross-sectional views of another semiconductor device at various stages of its fabrication process, according to some embodiments. The semiconductor device exemplified by FIGS. 5A-5G may be formed by the method 300 described in FIG. 3 and is similar to the semiconductor device exemplified in FIGS. 4A-4G.

The semiconductor device exemplified by FIGS. 5A-5G differs from the semiconductor device exemplified in FIGS. 4A-4G in that at operation 335, the shaping includes etching the second bottom electrode layer 514, RRAM dielectric layer 516, first top electrode layer 518, second top electrode layer 520, and second insulator layer 522; and at operation 337, the shaping the side wall layer involves removing (e.g., via etching operations) the sidewall layer from over the first bottom electrode layer 512, while leaving some of the side wall layer 424 over the second bottom electrode layer 514 and on sides of the RRAM dielectric layer 516, first top electrode layer 518, second top electrode layer 520 and the second insulator layer 522.

Referring to the example of FIG. 5A, in an embodiment of operation 332, a first insulator layer 502 is formed over a metal line 504 and interlayer dielectric (ILD) layer 506 of an interconnection structure. In various embodiments, the first insulator is formed by a suitable deposition technique.

Referring to the example of FIG. 5B, in an embodiment of operation 333, an opening 508 is formed in the first insulator layer 502 over a metal conductive line 504. In various embodiments, the opening is formed by patterning operations and a suitable etching technique.

Referring to the example of FIG. 5C, in an embodiment of operation 334, an RRAM film stack 510 is formed over the first insulator layer 502 and in the opening 508. The RRAM film stack 510 includes a bottom electrode comprising a first bottom electrode layer 512 and a second bottom electrode layer 514, an RRAM dielectric layer 516 disposed over the bottom electrode, a top electrode comprising a first top electrode layer 518 and a second top electrode layer 520, and a second insulator layer 522. In various embodiments, the RRAM film stack 510 may be formed using suitable deposition techniques.

Referring to the example of FIG. 5D, in an embodiment of operation 335, the RRAM film stack 510 has been etched into the shape of an RRAM cell. In particular, the second bottom electrode layer 514, RRAM dielectric layer 516, first top electrode layer 518, second top electrode layer 520, and second insulator layer 522 have been etched.

Referring to the example of FIG. 5E, in an embodiment of operation 336, a side wall layer 524 has been formed over the RRAM film stack 510.

Referring to the example of FIG. 5F, in an embodiment of operation 337, the side wall 526 has been shaped to form the RRAM cell 528.

Referring to the example of FIG. 5G, in an embodiment of operation 340, a vertical forming-voltage treatment area 530 is formed in the outer region of the RRAM cell 528.

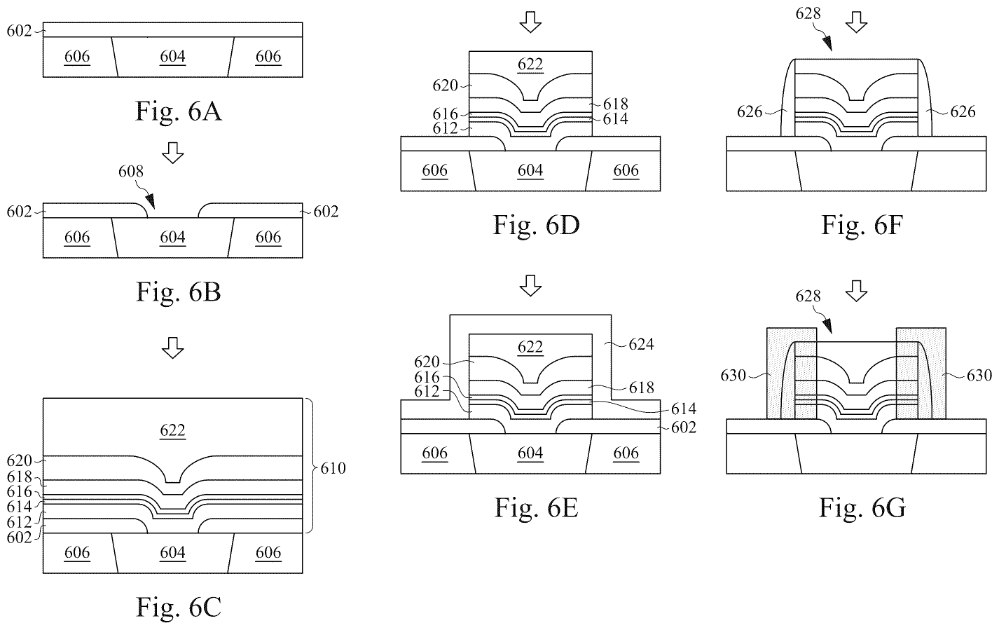

FIGS. 6A-6G are schematic cross-sectional views of another semiconductor device at various stages of its fabrication process, according to some embodiments. The semiconductor device exemplified by FIGS. 6A-6G may be formed by the method 300 described in FIG. 3 and is similar to the semiconductor device exemplified in FIGS. 4A-4G.

The semiconductor device exemplified by FIGS. 6A-6G differs from the semiconductor device exemplified in FIGS. 4A-4G in that at operation 335, the shaping includes etching the first bottom electrode layer 612, second bottom electrode layer 614, RRAM dielectric layer 616, first top electrode layer 618, second top electrode layer 620, and second insulator layer 622; and at operation 337, the shaping the side wall layer involves removing (e.g., via etching operations) the sidewall layer from over the first bottom electrode layer 612, while leaving some of the side wall layer 424 over the first insulator layer 602 and on sides of the first bottom electrode layer 612, second bottom electrode layer 614, RRAM dielectric layer 616, first top electrode layer 618, second top electrode layer 620 and the second insulator layer 622.

Referring to the example of FIG. 6A, in an embodiment of operation 332, a first insulator layer 602 is formed over a metal line 604 and interlayer dielectric (ILD) layer 606 of an interconnection structure. In various embodiments, the first insulator is formed by a suitable deposition technique.

Referring to the example of FIG. 6B, in an embodiment of operation 333, an opening 608 is formed in the first insulator layer 602 over a metal conductive line 604. In various embodiments, the opening is formed by patterning operations and a suitable etching technique.

Referring to the example of FIG. 6C, in an embodiment of operation 334, an RRAM film stack 610 is formed over the first insulator layer 602 and in the opening 608. The RRAM film stack 610 includes a bottom electrode comprising a first bottom electrode layer 612 and a second bottom electrode layer 614, an RRAM dielectric layer 616 disposed over the bottom electrode, a top electrode comprising a first top electrode layer 618 and a second top electrode layer 620, and a second insulator layer 622. In various embodiments, the RRAM film stack 610 may be formed using suitable deposition techniques.

Referring to the example of FIG. 6D, in an embodiment of operation 335, the RRAM film stack 610 has been etched into the shape of an RRAM cell. In particular, the second bottom electrode layer 614, RRAM dielectric layer 616, first top electrode layer 618, second top electrode layer 620, and second insulator layer 622 have been etched.

Referring to the example of FIG. 6E, in an embodiment of operation 336, a side wall layer 624 has been formed over the RRAM film stack 610.

Referring to the example of FIG. 6F, in an embodiment of operation 337, the side wall 626 has been shaped to form the RRAM cell 628.

Referring to the example of FIG. 6G, in an embodiment of operation 340, a vertical forming-voltage treatment area 630 is formed in the outer region of the RRAM cell 628.

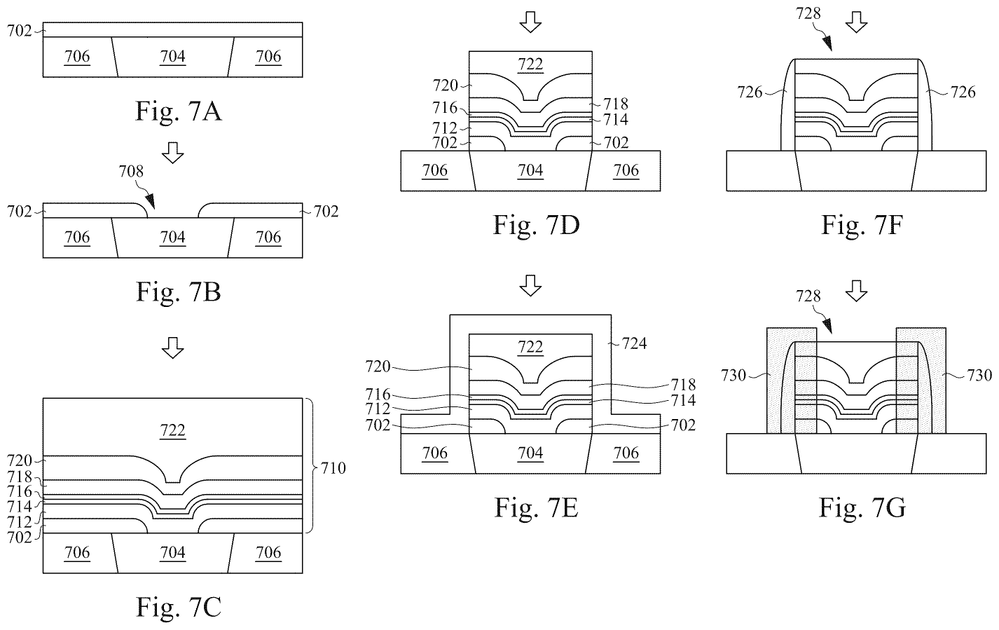

FIGS. 7A-7G are schematic cross-sectional views of another semiconductor device at various stages of its fabrication process, according to some embodiments. The semiconductor device exemplified by FIGS. 7A-7G may be formed by the method 300 described in FIG. 3 and is similar to the semiconductor device exemplified in FIGS. 4A-4G.

The semiconductor device exemplified by FIGS. 7A-7G differs from the semiconductor device exemplified in FIGS. 4A-4G in that at operation 335, the shaping includes etching the first insulator layer 702, first bottom electrode layer 712, second bottom electrode layer 714, RRAM dielectric layer 716, first top electrode layer 718, second top electrode layer 720, and second insulator layer 722; and at operation 337, the shaping the side wall layer involves removing (e.g., via etching operations) the sidewall layer from over the ILD layer 706, while leaving some of the side wall layer 724 over the ILD layer 706 and on sides of the first insulator layer 702, first bottom electrode layer 712, second bottom electrode layer 714, RRAM dielectric layer 716, first top electrode layer 718, second top electrode layer 720 and the second insulator layer 722.

Referring to the example of FIG. 7A, in an embodiment of operation 332, a first insulator layer 702 is formed over a metal line 704 and interlayer dielectric (ILD) layer 706 of an interconnection structure. In various embodiments, the first insulator is formed by a suitable deposition technique.

Referring to the example of FIG. 7B, in an embodiment of operation 333, an opening 708 is formed in the first insulator layer 702 over a metal conductive line 704. In various embodiments, the opening is formed by patterning operations and a suitable etching technique.

Referring to the example of FIG. 7C, in an embodiment of operation 334, an RRAM film stack 710 is formed over the first insulator layer 702 and in the opening 708. The RRAM film stack 710 includes a bottom electrode comprising a first bottom electrode layer 712 and a second bottom electrode layer 714, an RRAM dielectric layer 716 disposed over the bottom electrode, a top electrode comprising a first top electrode layer 718 and a second top electrode layer 720, and a second insulator layer 722. In various embodiments, the RRAM film stack 710 may be formed using suitable deposition techniques.

Referring to the example of FIG. 7D, in an embodiment of operation 335, the RRAM film stack 710 has been etched into the shape of an RRAM cell. In particular, the first insulator layer 702, first bottom electrode layer 712, second bottom electrode layer 714, RRAM dielectric layer 716, first top electrode layer 718, second top electrode layer 720, and second insulator layer 722 have been etched.

Referring to the example of FIG. 7E, in an embodiment of operation 336, a side wall layer 724 has been formed over the RRAM film stack 710.

Referring to the example of FIG. 7F, in an embodiment of operation 337, the side wall 726 has been shaped to form the RRAM cell 728.

Referring to the example of FIG. 7G, in an embodiment of operation 340, a vertical forming-voltage treatment area 730 is formed in the outer region of the RRAM cell 728.

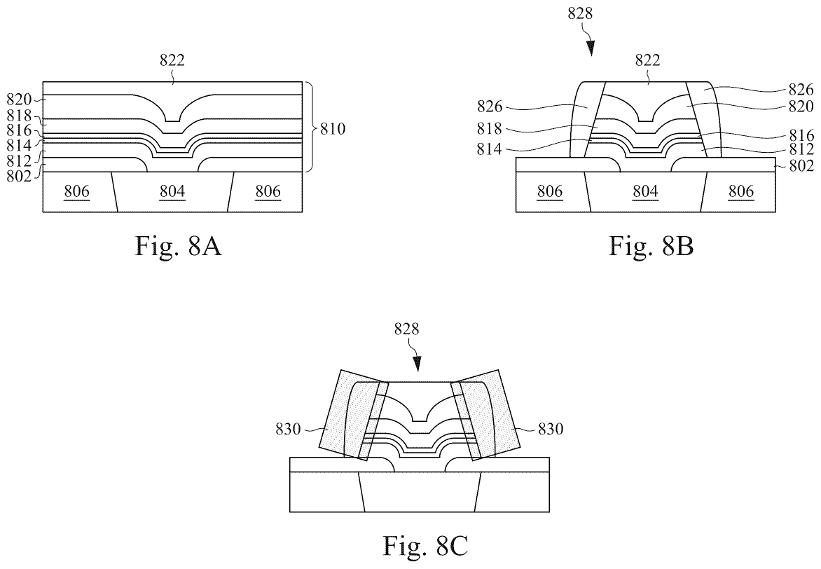

FIGS. 8A-8C are schematic cross-sectional views of another semiconductor device at various stages of its fabrication process, according to some embodiments. The semiconductor device exemplified by FIGS. 8A-8C may be formed by the method 300 described in FIG. 3 and is similar to the semiconductor device exemplified in FIGS. 6C, 6F, and 6G.

The semiconductor device exemplified by FIGS. 8A-8C differs from the semiconductor device exemplified in FIGS. 6C, 6F, and 6G in that at operation 335, the shaping includes etching the first insulator layer 802 (which is formed over a metal line 804 and ILD layer 806 of an interconnection structure), first bottom electrode layer 812, second bottom electrode layer 814, RRAM dielectric layer 816, first top electrode layer 818, second top electrode layer 820, and second insulator layer 822 into a trapezoidal-like shape.

Referring to the example of FIG. 8A, in an embodiment of operation 334, an RRAM film stack 810 is formed over the first insulator layer 802 and in the opening (not shown) in the first insulator layer 802. The RRAM film stack 810 includes a bottom electrode comprising a first bottom electrode layer 812 and a second bottom electrode layer 814, an RRAM dielectric layer 816 disposed over the bottom electrode, a top electrode comprising a first top electrode layer 818 and a second top electrode layer 820, and a second insulator layer 822. In various embodiments, the RRAM film stack 810 may be formed using suitable deposition techniques.

Referring to the example of FIG. 8B, in an embodiment of operations 335-337, the RRAM film stack 810 has been etched into the shape of an RRAM cell, a side wall layer has been formed over the RRAM film stack 810, and the side wall layer has been shaped into a side wall 826. In particular, the first bottom electrode layer 812, second bottom electrode layer 814, RRAM dielectric layer 816, first top electrode layer 818, second top electrode layer 820, and second insulator layer 822 have been etched in a trapezoidal-like shape and a side wall 826 has been formed above the first insulator layer 802 and on the side of the first bottom electrode layer 812, second bottom electrode layer 814, RRAM dielectric layer 816, first top electrode layer 818, second top electrode layer 820, and second insulator layer 822.

Referring to the example of FIG. 8C, in an embodiment of operation 340, a vertical forming-voltage treatment area 830 is formed in the outer region of the RRAM cell 828. In this example, the vertical forming-voltage treatment area 830 is angled in a manner similar to the angle of the trapezoidal-like shaped etching.

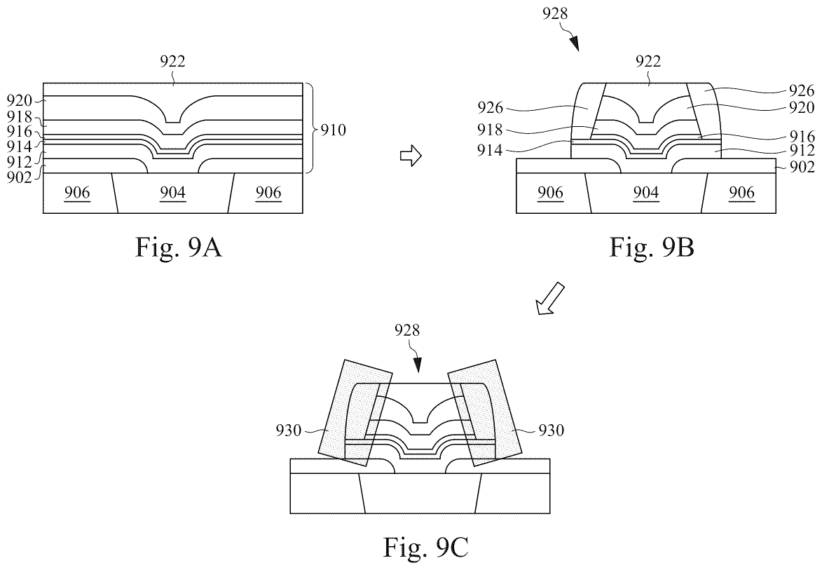

FIGS. 9A-9C are schematic cross-sectional views of another semiconductor device at various stages of its fabrication process, according to some embodiments. The semiconductor device exemplified by FIGS. 9A-9C may be formed by the method 300 described in FIG. 3 and is similar to the semiconductor device exemplified in FIGS. 5C, 5F, and 5G.

The semiconductor device exemplified by FIGS. 9A-9C differs from the semiconductor device exemplified in FIGS. 5C, 5F, and 5G in that at operation 335, the shaping includes etching the RRAM dielectric layer 916, first top electrode layer 918, second top electrode layer 920, and second insulator layer 922 into a trapezoidal-like shape.

Referring to the example of FIG. 9A, in an embodiment of operation 334, an RRAM film stack 910 is formed over the first insulator layer 902 (which is formed over a metal line 904 and ILD layer 906 of an interconnection structure) and in the opening (not shown) in the first insulator layer 902. The RRAM film stack 910 includes a bottom electrode comprising a first bottom electrode layer 912 and a second bottom electrode layer 914, an RRAM dielectric layer 916 disposed over the bottom electrode, a top electrode comprising a first top electrode layer 918 and a second top electrode layer 920, and a second insulator layer 922. In various embodiments, the RRAM film stack 910 may be formed using suitable deposition techniques.

Referring to the example of FIG. 9B, in an embodiment of operations 335-337, the RRAM film stack 910 has been etched into the shape of an RRAM cell, a side wall layer has been formed over the RRAM film stack 910, and the side wall layer has been shaped into a side wall 926. In particular, the RRAM dielectric layer 916, first top electrode layer 918, second top electrode layer 920, and second insulator layer 922 have been etched in a trapezoidal-like shape and a side wall 926 has been formed above the second bottom electrode layer 914 and on the side of the RRAM dielectric layer 916, first top electrode layer 918, second top electrode layer 920, and second insulator layer 922.

Referring to the example of FIG. 9C, in an embodiment of operation 340, a vertical forming-voltage treatment area 930 is formed in the outer region of the RRAM cell 928. In this example, the vertical forming-voltage treatment area 930 is angled in a manner similar to the angle of the trapezoidal-like shaped etching.

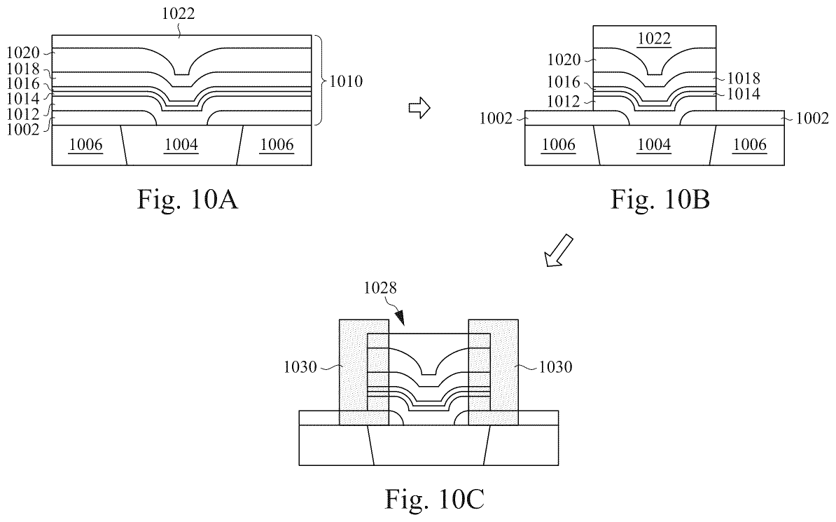

FIGS. 10A-10C are schematic cross-sectional views of another semiconductor device at various stages of its fabrication process, according to some embodiments. The semiconductor device exemplified by FIGS. 10A-10C may be formed by the method 300 described in FIG. 3 and is similar to the semiconductor device exemplified in FIGS. 6C, 6D, and 6G.

The semiconductor device exemplified by FIGS. 10A-10C differs from the semiconductor device exemplified in FIGS. 6C, 6D, and 6G in that operations 336 and 337 are not performed—a side wall is not formed.

Referring to the example of FIG. 10A, in an embodiment of operation 334, an RRAM film stack 1010 is formed over the first insulator layer 1002 (which is formed over a metal line 1004 and ILD layer 1006 of an interconnection structure) and in the opening (not shown) in the first insulator layer 1002. The RRAM film stack 1010 includes a bottom electrode comprising a first bottom electrode layer 1012 and a second bottom electrode layer 1014, an RRAM dielectric layer 1016 disposed over the bottom electrode, a top electrode comprising a first top electrode layer 1018 and a second top electrode layer 1020, and a second insulator layer 1022. In various embodiments, the RRAM film stack 1010 may be formed using suitable deposition techniques.

Referring to the example of FIG. 10B, in an embodiment of operation 335, the RRAM film stack 1010 has been etched into the shape of an RRAM cell. In particular, the first bottom electrode layer 1012, second bottom electrode layer 1014, RRAM dielectric layer 1016, first top electrode layer 1018, second top electrode layer 1020, and second insulator layer 1022 have been etched.

Referring to the example of FIG. 10C, in an embodiment of operation 340, a vertical forming-voltage treatment area 1030 is formed in the outer region of the RRAM cell 1028.

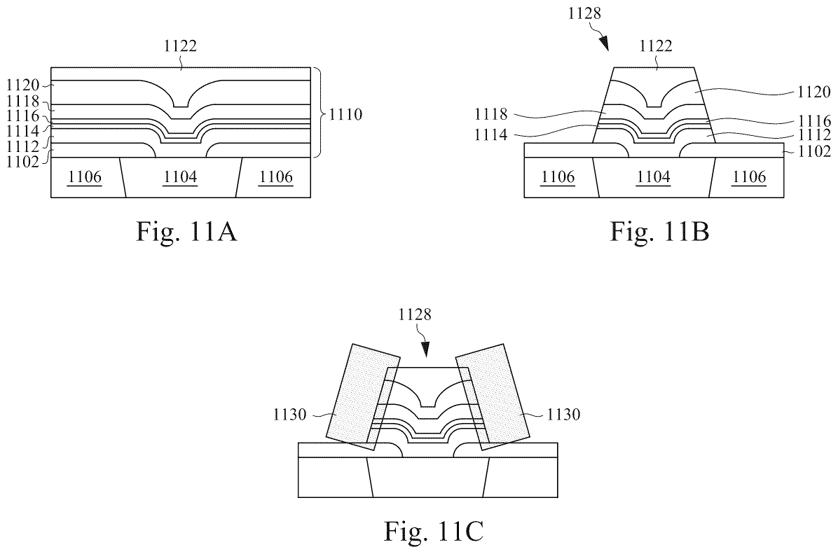

FIGS. 11A-11C are schematic cross-sectional views of another semiconductor device at various stages of its fabrication process, according to some embodiments. The semiconductor device exemplified by FIGS. 11A-11C may be formed by the method 300 described in FIG. 3 and is similar to the semiconductor device exemplified in FIGS. 8A, 8B, and 8C.

The semiconductor device exemplified by FIGS. 11A-11C differs from the semiconductor device exemplified in FIGS. 8A, 8B, and 8C in that operations 336 and 337 are not performed—a side wall is not formed.

Referring to the example of FIG. 11A, in an embodiment of operation 334, an RRAM film stack 1110 is formed over the first insulator layer 1102 (which is formed over a metal line 1104 and ILD layer 1106 of an interconnection structure) and in the opening (not shown) in the first insulator layer 1102. The RRAM film stack 1110 includes a bottom electrode comprising a first bottom electrode layer 1112 and a second bottom electrode layer 1114, an RRAM dielectric layer 1116 disposed over the bottom electrode, a top electrode comprising a first top electrode layer 1118 and a second top electrode layer 1120, and a second insulator layer 1122. In various embodiments, the RRAM film stack 1110 may be formed using suitable deposition techniques.

Referring to the example of FIG. 11B, in an embodiment of operation 335, the RRAM film stack 1110 has been etched into the shape of an RRAM cell. In particular, the first bottom electrode layer 1112, second bottom electrode layer 1114, RRAM dielectric layer 1116, first top electrode layer 1118, second top electrode layer 1120, and second insulator layer 1122 have been etched.

Referring to the example of FIG. 11C, in an embodiment of operation 340, a vertical forming-voltage treatment area 1130 is formed in the outer region of the RRAM cell 1128.

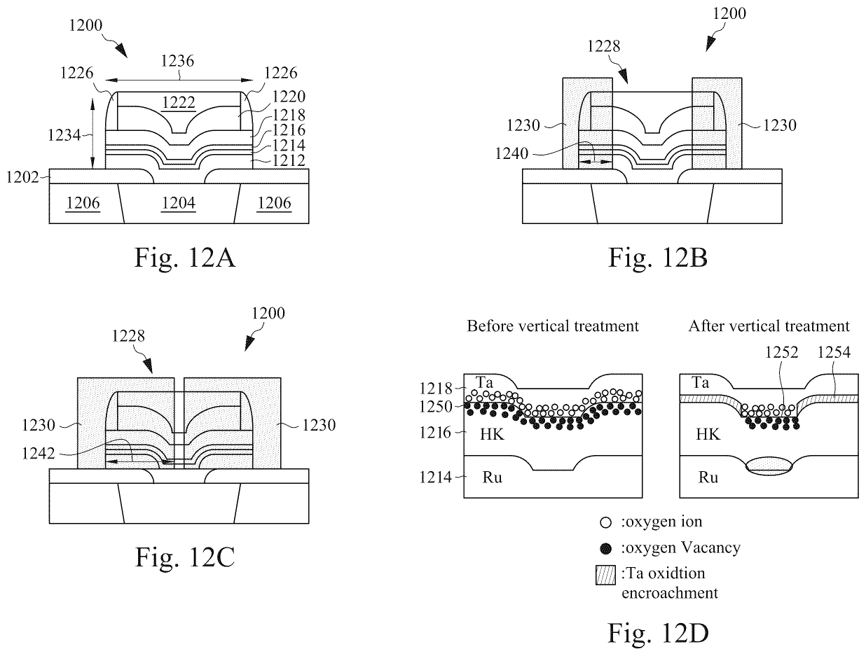

FIG. 12A is a schematic cross-sectional view of an example semiconductor device 1200, according to some embodiments. The example semiconductor device 1200 includes a first insulator layer 1202 (which is formed over a metal line 1204 and ILD layer 1206 of an interconnection structure), a bottom electrode comprising a first bottom electrode layer 1212 and a second bottom electrode layer 1214, an RRAM dielectric layer 1216 disposed over the bottom electrode, a top electrode comprising a first top electrode layer 1218 and a second top electrode layer 1220, a second insulator layer 1222, and a side wall 1226. The example semiconductor device 1200 has a height 1234 that is between 100 Å (angstroms) and 2000 Å, and a width 1236 that is between 200 Å and 2000 Å.

FIGS. 12B and 12C are schematic cross-sectional views of the example semiconductor device 1200 after vertical treatment, according to various embodiments. Illustrated are a vertical forming-voltage treatment area 1230 formed on the RRAM cell 1228 after a vertical treatment on sides sections of the RRAM cell 1228, wherein the vertical treatment comprises a heat treatment configured to cause a reduction in diameter of a forming effective region in the RRAM structure near a border between the RRAM dielectric layer and the top electrode. The forming effective region is configured to cause the RRAM structure to undergo a reversible change between a high resistance state associated with a first data state and a low resistance state associated with a second data state. FIG. 12B illustrates that the vertical forming-voltage treatment area 1230 extends into the RRAM cell 1228 a distance 1240 that is greater than 10% of a radius of the RRAM cell 1228. FIG. 12C illustrates that the vertical forming-voltage treatment area 1230 extends into the RRAM cell 1228 a distance 1242 that is less than 90% of the radius of the RRAM cell 1228.

FIG. 12D are cross-sectional views of an example semiconductor structure before vertical treatment and after vertical treatment. Shown are a second bottom electrode layer 1214, an RRAM dielectric layer 1216, and a first top electrode layer 1218. A forming effective region 1250 is formed in the RRAM structure near a border between the RRAM dielectric layer 1216 and the first top electrode layer 1218. The forming effective region is configured to cause the RRAM structure to undergo a reversible change between a high resistance state associated with a first data state and a low resistance state associated with a second data state.

After vertical treatment, a smaller forming effective region 1252 is disposed in the RRAM structure near the border between the RRAM dielectric layer 1216 and the first top electrode layer 1218, and an oxidation encroachment region 1254 is disposed outside of the forming effective region 1252 near the border between the RRAM dielectric layer 1216 and the first top electrode layer 1218, wherein the oxidation encroachment region 1254 lacks oxygen ions and oxygen vacancies. In various embodiments, the forming effective region 1252 includes a higher concentration of oxygen ions than the oxidation encroachment region 1254 near the border between the RRAM dielectric layer 1216 and the first top electrode layer 1218 that is outside of the forming effective region 1252. In various embodiments, the forming effective region 1252 includes a higher concentration of oxygen vacancies than the oxidation encroachment region 1254 near the border between the RRAM dielectric layer 1216 and the first top electrode layer 1218 that is outside of the forming effective region 1250. In various embodiments, the forming effective region 1252 is outside of the vertical forming-voltage treatment area 1230. In various embodiments, the forming effective region 1252 has a width between 20% and 80% of a diameter of the RRAM structure.

Experimental data have shown that vertical treatments may prolong the useful life of RRAM cells. Experimental data have shown that after 20K on/off cycles, it may be difficult to read the difference between an on state and an off state for an RRAM cell that has not undergone vertical treatment. Thus, RRAM cells that have not undergone vertical treatment may not be reliably used in a memory device after 20K on/off cycles. In contrast, experimental data have shown that RRAM cells that have undergone vertical treatment may be reliably used in a memory device after 20K on/off cycles. Vertical treatment may extend the useful life of RRAM cells beyond 20K on/off cycles.

Experimental data have also shown that RRAM cells that have undergone vertical treatment may have a lower average forming voltage, lower maximum forming voltage, lower minimum forming voltage, and/or lower range of forming voltages than RRAM cells that have not undergone vertical treatment.

In the foregoing examples, the illustrated transistor was a planar transistor, such as an FET or MOSFET. In other examples, non-planar transistors, such as FINFET may be used. As with the other method embodiments and exemplary devices discussed herein, it is understood that parts of the semiconductor devices may be fabricated by typical semiconductor technology process flow, and thus some processes are only briefly described herein. Further, the exemplary semiconductor devices may include various other devices and features, such as other types of devices such as additional transistors, bipolar junction transistors, resistors, capacitors, inductors, dials, fuses, and or other logic devices, etc., but is simplified for better understanding of concepts of the present disclosure. In some embodiments, exemplary devices include a plurality of semiconductor devices (e.g., transistors), including PFETs, NFETs, etc., which may be interconnected.

In some aspects, the techniques described herein relate to a device structure, including: a bottom electrode surrounded by a lower insulator layer; a dielectric layer disposed over the bottom electrode; a top electrode disposed over the dielectric layer; a vertical forming-voltage treatment area in an outer region of the device structure, the outer region including side regions of the bottom electrode, the dielectric layer, and the top electrode; and a forming effective region in an interior region of the device structure spaced away from a lateral edge the device structure and near a border between the dielectric layer and the top electrode, the forming effective region configured to cause the device structure to undergo a reversible change between a high resistance state associated with a first data state and a low resistance state associated with a second data state.

In some aspects, the techniques described herein relate to a device structure, wherein the vertical forming-voltage treatment area extends into the device structure a distance that is greater than 10% of a radius of the device structure and less than 90% of the radius of the device structure.

In some aspects, the techniques described herein relate to a device structure, wherein the vertical forming-voltage treatment area includes a dopant including one or more of Oxygen (O), Nitrogen (N), Hydrogen (H), Fluorine (F), Carbon (C), Chlorine (Cl), and carbon tetrafluoride (CF4).

In some aspects, the techniques described herein relate to a device structure, wherein a ratio of dopant to metal compounds in the vertical forming-voltage treatment area of the top electrode is greater than or equal to 5%.

In some aspects, the techniques described herein relate to a device structure, wherein the vertical forming-voltage treatment area has been exposed to a heat treatment configured to cause a reduction in a lateral dimension of the forming effective region.

In some aspects, the techniques described herein relate to a device structure, wherein the forming effective region is outside of the vertical forming-voltage treatment area.

In some aspects, the techniques described herein relate to a device structure, wherein the forming effective region has a width between 20% and 80% of a diameter of the device structure.

In some aspects, the techniques described herein relate to a method including: forming a device structure by depositing a film, the device structure including a bottom electrode surrounded by a lower insulator layer, a dielectric layer disposed over the bottom electrode, a top electrode disposed over the dielectric layer, and an upper insulator disposed over the top electrode; and performing a vertical treatment on side sections of the device structure, the vertical treatment including a heat treatment configured to cause a reduction in diameter of a forming effective region in the device structure near a border between the dielectric layer and the top electrode; wherein the forming effective region is configured to cause the device structure to undergo a reversible change between a high resistance state associated with a first data state and a low resistance state associated with a second data state.

In some aspects, the techniques described herein relate to a method, wherein performing the vertical treatment further includes doping the side sections with a dopant including one or more of Oxygen (O), Nitrogen (N), Hydrogen (H), Fluorine (F), Carbon (C), Chlorine (Cl), and carbon tetrafluoride (CF4).

In some aspects, the techniques described herein relate to a method, wherein performing the vertical treatment includes forming a vertical forming-voltage treatment area in an outer region of the device structure, the outer region including side regions of the bottom electrode, the dielectric layer, the top electrode, and the upper insulator.

In some aspects, the techniques described herein relate to a method, wherein the forming effective region is outside of the vertical forming-voltage treatment area.

In some aspects, the techniques described herein relate to a method, wherein the forming effective region includes a higher concentration of oxygen ions than a second region (e.g., an oxidation encroachment region) near the border between the dielectric layer and the top electrode that is outside of the forming effective region.

In some aspects, the techniques described herein relate to a method, wherein the forming effective region includes a higher concentration of oxygen vacancies than a second region (e.g., an oxidation encroachment region) near the border between the dielectric layer and the top electrode that is outside of the forming effective region.

In some aspects, the techniques described herein relate to a method, further including forming an oxidation encroachment region outside of the forming effective region near the border between the dielectric layer and the top electrode, wherein the oxidation encroachment region lacks oxygen ions and oxygen vacancies.

In some aspects, the techniques described herein relate to a memory array, including: a plurality of memory cells, each cell including a bottom electrode surrounded by a lower insulator layer, a dielectric layer disposed over the bottom electrode, a top electrode disposed over the dielectric layer, and an upper insulator disposed over the top electrode; and a vertical forming-voltage treatment area in an outer region of the plurality of memory cells, the outer region including side regions of the bottom electrode, the dielectric layer, the top electrode, and the upper insulator in the plurality of memory cells; wherein the vertical forming-voltage treatment area has been exposed to a heat treatment configured to cause a reduction in a lateral dimension of a forming effective region in the plurality of memory cells that is configured to cause its memory cell to undergo a reversible change between a high resistance state associated with a first data state and a low resistance state associated with a second data state.

In some aspects, the techniques described herein relate to a memory array, wherein the forming effective region is outside of the vertical forming-voltage treatment area.

In some aspects, the techniques described herein relate to a memory array, wherein the forming effective region has a width between 20% and 80% of a diameter of a memory cell.

In some aspects, the techniques described herein relate to a memory array, wherein the forming effective region includes a higher concentration of oxygen ions than a second region (e.g., an oxidation encroachment region) near a border between the dielectric layer and the top electrode that is outside of the forming effective region.

In some aspects, the techniques described herein relate to a memory array, wherein the forming effective region includes a higher concentration of oxygen vacancies than a second region (e.g., an oxidation encroachment region) near a border between the dielectric layer and the top electrode that is outside of the forming effective region.

In some aspects, the techniques described herein relate to a memory array, wherein the plurality of memory cells further include an oxidation encroachment region outside of the forming effective region near a border between the dielectric layer and the top electrode, wherein the oxidation encroachment region lacks oxygen ions and oxygen vacancies.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A device structure, comprising:
a bottom electrode surrounded by a lower insulator layer;
a dielectric layer disposed over the bottom electrode;
a top electrode disposed over the dielectric layer;
a vertical forming-voltage treatment area in an outer region of the device structure, the outer region comprising side regions of the bottom electrode, the dielectric layer, and the top electrode; and
a forming effective region in an interior region of the device structure spaced away from a lateral edge the device structure and near a border between the dielectric layer and the top electrode, the forming effective region configured to cause the device structure to undergo a reversible change between a high resistance state associated with a first data state and a low resistance state associated with a second data state.

2. The device structure of claim 1, wherein the vertical forming-voltage treatment area extends into the device structure a distance that is greater than 10% of a radius of the device structure and less than 90% of the radius of the device structure.

3. The device structure of claim 1, wherein the vertical forming-voltage treatment area includes a dopant comprising one or more of Oxygen (O), Nitrogen (N), Hydrogen (H), Fluorine (F), Carbon (C), Chlorine (Cl), and carbon tetrafluoride (CF₄).

4. The device structure of claim 1, wherein a ratio of dopant to metal compounds in the vertical forming-voltage treatment area of the top electrode is greater than or equal to 5%.

5. The device structure of claim 1, wherein the vertical forming-voltage treatment area has been exposed to a heat treatment configured to cause a reduction in a lateral dimension of the forming effective region.

6. The device structure of claim 1, wherein the forming effective region is outside of the vertical forming-voltage treatment area.

7. The device structure of claim 1, wherein the forming effective region has a width between 20% and 80% of a diameter of the device structure.

8. A method comprising:
forming a device structure by depositing a film, the device structure comprising a bottom electrode surrounded by a lower insulator layer, a dielectric layer disposed over the bottom electrode, a top electrode disposed over the dielectric layer, and an upper insulator disposed over the top electrode; and
performing a vertical treatment on side sections of the device structure, the vertical treatment comprising a heat treatment configured to cause a reduction in diameter of a forming effective region in the device structure near a border between the dielectric layer and the top electrode;
wherein the forming effective region is configured to cause the device structure to undergo a reversible change between a high resistance state associated with a first data state and a low resistance state associated with a second data state.

9. The method of claim 8, wherein performing the vertical treatment further comprises doping the side sections with a dopant comprising one or more of Oxygen (O), Nitrogen (N), Hydrogen (H), Fluorine (F), Carbon (C), Chlorine (Cl), and carbon tetrafluoride (CF₄).

10. The method of claim 9, wherein performing the vertical treatment comprises forming a vertical forming-voltage treatment area in an outer region of the device structure, the outer region comprising side regions of the bottom electrode, the dielectric layer, the top electrode, and the upper insulator.

11. The method of claim 10, wherein the forming effective region is outside of the vertical forming-voltage treatment area.

12. The method of claim 8, wherein the forming effective region includes a higher concentration of oxygen ions than a second region (e.g., an oxidation encroachment region) near the border between the dielectric layer and the top electrode that is outside of the forming effective region.

13. The method of claim 8, wherein the forming effective region includes a higher concentration of oxygen vacancies than a second region (e.g., an oxidation encroachment region) near the border between the dielectric layer and the top electrode that is outside of the forming effective region.

14. The method of claim 8, further comprising forming an oxidation encroachment region outside of the forming effective region near the border between the dielectric layer and the top electrode, wherein the oxidation encroachment region lacks oxygen ions and oxygen vacancies.

15. A memory array, comprising:
a plurality of memory cells, each cell comprising a bottom electrode surrounded by a lower insulator layer, a dielectric layer disposed over the bottom electrode, a top electrode disposed over the dielectric layer, and an upper insulator disposed over the top electrode; and
a vertical forming-voltage treatment area in an outer region of the plurality of memory cells, the outer region comprising side regions of the bottom electrode, the dielectric layer, the top electrode, and the upper insulator in the plurality of memory cells;
wherein the vertical forming-voltage treatment area has been exposed to a heat treatment configured to cause a reduction in a lateral dimension of a forming effective region in the plurality of memory cells that is configured to cause its memory cell to undergo a reversible change between a high resistance state associated with a first data state and a low resistance state associated with a second data state.

16. The memory array of claim 15, wherein the forming effective region is outside of the vertical forming-voltage treatment area.

17. The memory array of claim 15, wherein the forming effective region has a width between 20% and 80% of a diameter of an memory cell.

18. The memory array of claim 15, wherein the forming effective region includes a higher concentration of oxygen ions than a second region (e.g., an oxidation encroachment region) near a border between the dielectric layer and the top electrode that is outside of the forming effective region.

19. The memory array of claim 15, wherein the forming effective region includes a higher concentration of oxygen vacancies than a second region (e.g., an oxidation encroachment region) near a border between the dielectric layer and the top electrode that is outside of the forming effective region.

20. The memory array of claim 15, wherein the plurality of memory cells further comprise an oxidation encroachment region outside of the forming effective region near a border between the dielectric layer and the top electrode, wherein the oxidation encroachment region lacks oxygen ions and oxygen vacancies.
